(19) United States
(12) Patent Application Publication
(10) Pub. No.: US 2023/0348261 A1
(43) Pub. Date: Nov. 2, 2023

(54) ACCELEROMETER-BASED ACOUSTIC BEAMFORMER VECTOR SENSOR WITH COLLOCATED MEMS MICROPHONE

(71) Applicant: AIVS Inc., Seattle, WA (US)

(72) Inventors: James W. Waite, Eastsound, WA (US); David Raymond Dall'Osto, Seattle, WA (US)

(21) Appl. No.: 18/140,174

(22) Filed: Apr. 27, 2023

Related U.S. Application Data
(60) Provisional application No. 63/335,879, filed on Apr. 28, 2022.

(51) Int. Cl. B81B 7/02; G01P 15/18; H04R 29/00

(52) U.S. Cl. CPC B81B 7/02; G01P 15/18; H04R 29/004; B81B 2201/0235; B81B 2201/0257; B81B 2207/015; H04R 2201/003

(57) ABSTRACT

A method and apparatus to improve the performance of acoustic beamformers composed of accelerometer-based Acoustic Vector Sensors (AVS) is disclosed. Most AVS are composed of a set of spatially separated microphones, for which tradeoffs exist based on the array size and number of elements, geometry, frequency bandwidth, and system cost. Accelerometer-based AVS are composed of a one or more triaxial accelerometers, each paired with a collocated MEMS microphone. This results in much smaller array apertures for equivalent performance, and a significant reduction in unwanted sidelobes. A real-time beamformer algorithm using this MEMS accelerometer-enabled 3D sensing technology allows the system to focus on specific areas or sources of noise, delivering more precise monitoring and identification of noise sources, which is useful for noise reduction efforts and compliance with noise regulations

### RELATED APPLICATIONS

This application claims the benefit of the earlier priority date of U.S. Provisional Patent Application No. 63/335,879, entitled “ACCELEROMETER-BASED INTENSITY VECTOR SENSOR WITH COLLOCATED MEMS MICROPHONE filed on Apr. 28, 2022, which is expressly incorporated herein by reference in its entirety.

### STATEMENT OF GOVERNMENT INTEREST

The invention described herein may be manufactured, used, and licensed by or for the United States Government without the payment of royalties. The subject matter of this application is at least partially supported by the U.S. Army Research Laboratory, 2800 Powder Mill Rd., Adelphi, MD 20783-1197, under Small Business Innovative Research contract number W911QX21C0020.

### TECHNICAL FIELD

Examples of the disclosure are related to airborne acoustic vector sensors, including devices which measure particle velocity, and/or sound intensity in one or more dimensions in air, and arrays of such sensors configured as an airborne acoustic beamformer.

### BRIEF DESCRIPTION OF THE DRAWINGS

FIG. 1 is a photograph of components of an example accelerometer-based acoustic vector sensor (AVS).

FIG. 2 is a photograph of an example accelerometer-based AVS sensor with both a microphone and the accelerometer encased within foam. The (normally open to air) microphone port is present as a small hole in the flex circuit printed circuit board. A top hemisphere is glued or otherwise attached to the surface depicted in the figure, covering the port.

FIG. 3 is a photograph of a complete example accelerometer-based AVS node, including processing electronics below the sensor.

FIG. 4 is a graph of an example accelerometer-based AVS foam-encased microphone transfer function (solid), relative to a reference microphone present in the same acoustic field outside the foam. The dashed trace is the applied correction, and the dotted trace is the resulting corrected microphone response. The corrected response provides a useful bandwidth of 2 kHz.

FIG. 5 is a photograph of an example prior art (patent FR3072533A1) AVS designed for environmental noise monitoring, composed of 4 microphones in a tetrahedral geometry.

FIG. 6 is a diagram of example beam patterns for single and dual AVS sensor configurations.

FIG. 7 is a graph of example 2D positioning azimuth angles φ₁ and φ₂ to triangulate the source position at point P.

FIG. 8 is a diagram of an example command and control panel for a multi-AVS network having geographically dispersed nodes.

FIG. 9 is a photograph of an example accelerometer-based AVS configured as a two-sensor noise radar for identification of noise hotspots on trains, or similarly for autonomous monitoring of directional noise from traffic, aircraft, or nearby industrial sites.

### DETAILED DESCRIPTION

An Acoustic Vector Sensor (AVS) for airborne measurements of particle velocity and sound intensity that employs a MEMS triaxial accelerometer and a MEMS microphone to derive acoustic intensity in three dimensions is described in U.S. patent application Ser. No. 17/332,390. Accelerometer-based AVS sensitivity is increased by enclosing the accelerometer in a very lightweight solid body, such as closed cell foam with a larger cross-section than the accelerometer. In that prior art, the MEMS microphone is mounted so that its venting port is exposed to air. These existing accelerometer-based AVSs have a microphone mounted as close to the accelerometer as possible, but outside the solid body. In an arbitrary sound field with unknown angle between a source and an AVS, measurements of acoustic intensity are most accurate when the phase center of the microphone and accelerometer coincide. Intensity can be expressed as:

[symbol]

=p [symbol] */2

where p is the scalar pressure, [symbol] is the triaxial particle velocity, and u* indicates the complex conjugate of u. Measuring the 3D intensity vector of a sound field as a function of frequency assumes that the pressure and velocity are measured at the same collocated position. If the phase center of the two measurements differs by just a few centimeters, this results in a measurement bias that depends on the arrival angle of the acoustic wave and is therefore very difficult to correct.

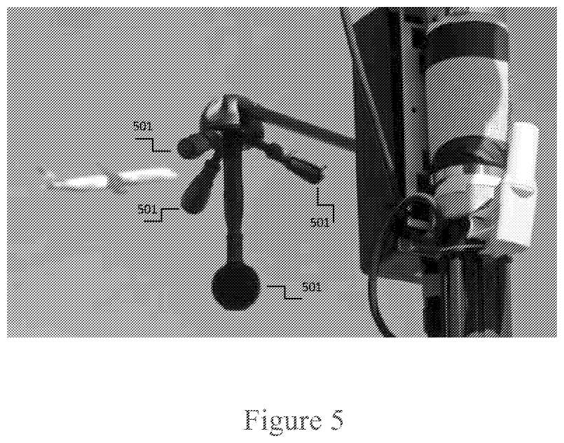

Prior art such as FR3072533A1 designed specifically for traffic noise monitoring and depicted in FIG. 5 rely of spatial separation of microphones, and thus are subject to detecting so-called ghost sources because of the presence of sidelobes, which can bias the directivity of the system. Likewise, acoustic cameras designed to capture sound direction utilize microphone arrays in many configurations, from spherical (U.S. Pat. No. 9,706,292B2) which require significant (GPU) processing horsepower to resolve direction, to ultra large planar microphone arrays that prioritize reduction of ghosting at the expense of physical size and complexity (U.S. Pat. No. 9,264,799B2).

An accelerometer-based AVS has been constructed in which the microphone is encased within the same lightweight closed cell foam as the accelerometer, such that the two sensors are separated by just a few millimeters. To offset the significant difference in microphone pressure response, a calibration method is disclosed to correct the performance of the sensor as if the pressure were measured in air. This permits accurate acoustic intensity estimation even when the MEMS microphone is encased in closed cell foam.

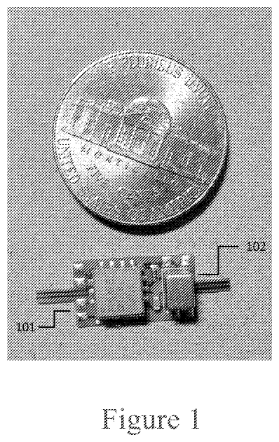

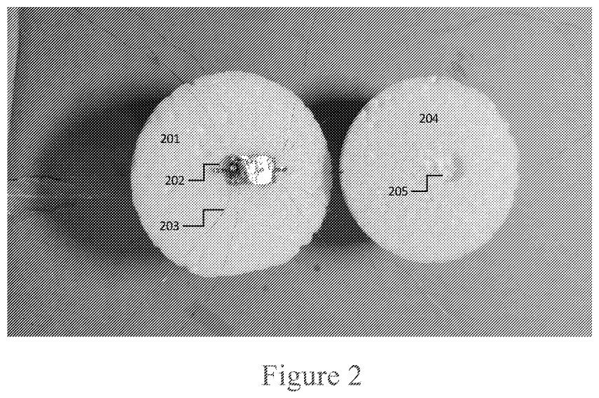

FIG. 1 is a photo of an example accelerometer-based AVS sensor components mounted on a small flex circuit board, including the MEMS accelerometer 101 on the left and a MEMS microphone 102 on the right. FIG. 2 shows the bottom side of the sensor board mounted in closed cell foam 201 having density only a few times that of air, or less, with the microphone port 202 circled and with copper wires 203 extending away from the foam.

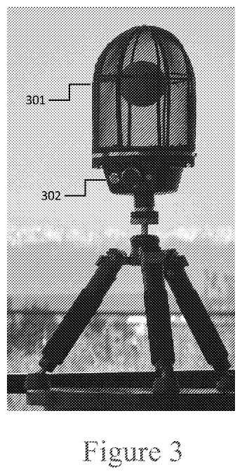

A complete AVS node is constructed by mating the foam hemisphere shown in FIG. 2 with a solid top half 204, gluing or otherwise attaching them together, and suspending the solid body in air from a framework via monofilament wires attached to a flexible suspension band, providing strain relief for the small gauge wires connected to processing electronics. A small pea-sized dimple 205 is left in the top hemisphere to detune the microphone response, and a waterproof glue can be used so that the sensor components are protected from moisture intrusion. FIG. 3 is a photo of a completed AVS 301 coupled to an IoT (Internet of Things) electronics and software system known as ARES (Acoustic Real-time Event Sensor) 302, such that the suspended sensor is exposed to sound fields in three dimensions, and performs calculations locally within the IoT device to scale the data and convert the measured acceleration and pressure to acoustic particle velocity and intensity. The micromesh windscreen enclosing the sensor is water repellent, but not resistant. Rain water and moisture can permeate through the micromesh windscreen, and collect on the foam solid body that encloses the sensor board. It is thus convenient that in the Accelerometer-based AVS design, both the accelerometer and microphone are encased within the foam, which provides good protection from the weather. Existing designs require separate weather protection for the microphone, which can increase the separation between the microphone and accelerometer yet more.

Advantages of collocating the microphone and accelerometer within the closed cell foam have been established. To benefit from these advantages, two tradeoffs are noted, and overcome if possible. The first is concerned with the increase in weight of the foam body due to the presence of the microphone. Note that the foam volume is present to amortize the weight of the accelerometer over a larger volume of air. U.S. patent application Ser. No. 17/332,390 shows how the effective sensitivity is reduced as a function of the density ratio between the solid body enclosing the accelerometer and the density of air. At present the lightest weight closed cell foam is about five times the density of air. Adding the weight of the accelerometer itself, the flex circuit board, solder, and some wires further increases this ratio. Thus, adding the additional weight of the microphone lowers the sensitivity compared to existing accelerometer-based AVS designs. A typical MEMS microphone weight of 0.1 grams increases the overall weight of the sensor by about 10%, which will reduce AVS sensitivity by about 1 dB for an AVS solid volume diameter of 6 cm. This is acceptable given the advantages.

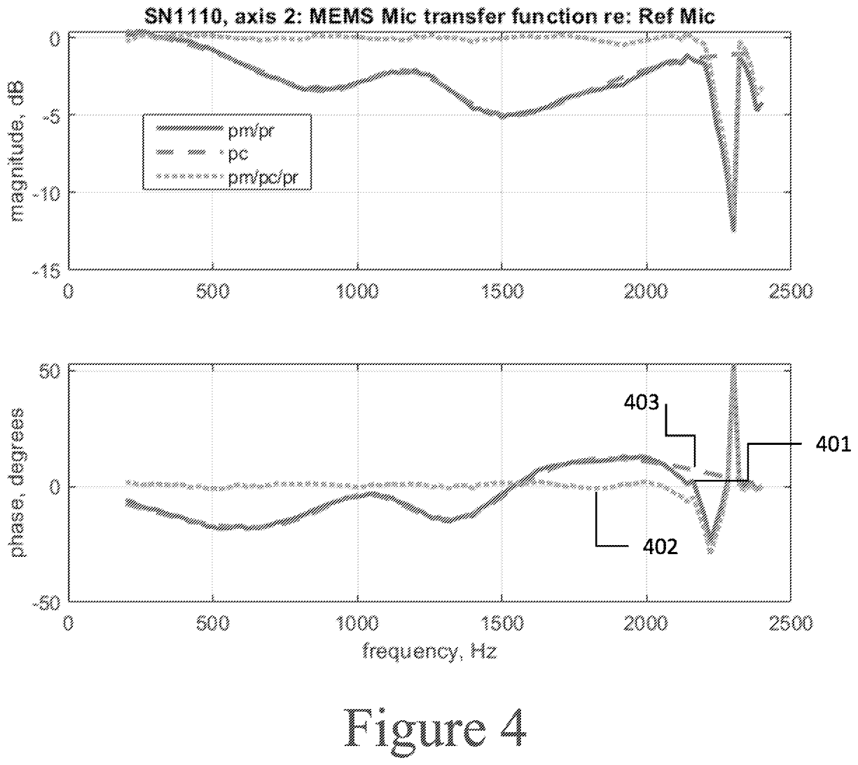

A second disadvantage of encasing the microphone within the closed cell foam body relates to the effect on the MEMS microphone response. As seen in FIG. 4, the solid 401 trace represents the transfer function of a foam-encased MEMS microphone relative to a reference microphone in the same acoustic field, but not surrounded by foam. As expected due to the dampening effect of the foam, several decibels (dB) of attenuation are observed in the response through the useful frequency range, and the phase response of the foam-encased microphone as a function of frequency is also affected. To mitigate these distortions, a complex vector correction (dashed trace 402) is implemented as a low-order digital filter generated by a fitting algorithm applied to the measured MEMS microphone data. The net result is the dotted trace 403 seen in FIG. 4, which brings the microphone response back to what is expected if it were not encased in foam. This correction can be applied in either the time or frequency domain.

Note that there are typically no resonances or anti-resonances in the bandwidth of interest, so that the calibration vector is stable over wide environmental conditions. This allows for a MEMS microphone calibration step in the Accelerometer-based AVS manufacturing process, such that the transfer function pictured in FIG. 4 is characterized, reduced to calibration coefficients, saved to non-volatile memory within the ARES IoT device 302, and reconstructed as a correction to be applied during practical use of the sensor in the field.

The method can be reduced to finding the coefficients of an unknown digital filter that when applied to an internal, encased microphone signal, results in a frequency response as if measured at the external microphone position, except (as desired) the phase center of the measurement remains at the internal position. This is a system identification problem, and can be solved using the Matlab function invfreqz( ), among other similar system identification tools. Upon specifying a filter order, the function optimally fits a curve to the complex-valued frequency response function. For a third order system, the function returns three numerator coefficients and three denominator coefficients that can be used later to correct the behavior of the encased microphone to act as one mounted outside the foam body, but at the same collocated position next to the accelerometer. Depending on the microphone, the order of the correction process illustrated here can vary from 2^{nd} to 5^{th} order, all of which are represented as stable digital filters that have diminished effect at low frequency. Further, by reducing the effects to a few coefficients, these corrections can be applied at any frequency within the accelerometer-based AVS bandwidth after reconstructing a frequency domain correction vector from the digital filter coefficients.

The described calibration and correction method can completely offset the disadvantage that the encased microphone does not correctly estimate the free field sound pressure present outside the microphone. Except for the slight reduction in sensitivity due to the increase in weight of the accelerometer-based AVS sensor, no other disadvantage may remain. Certain attributes of the design include improved robustness to precipitation, and reducing the phase offset that occurs when measurements at the microphone and accelerometer are combined to calculate intensity, which depends on the angle of incidence of the sound wave. This phase offset is now virtually zero, since the microphone and accelerometer are just a few millimeters apart as shown in FIG. 1. At the maximum accelerometer bandwidth of 2000 Hz, this gap is less than 3% of the wavelength, compared to 30% in previous designs.

Using this manufacturing technique, a combined triaxial MEMS accelerometer and single MEMS microphone have an effective aperture of just a few millimeters, the distance between the two devices on the flex circuit shown in FIG. 1. This can be a significant improvement when compared to an Acoustic Vector Sensor constructed of microphones exclusively, an example of which is shown in FIG. 5. Each of four sensing elements 501 may only measure pressure, so a microphone-based AVS relies on pressure gradients to measure directivity, and thus may require spatial separation among the elements to derive vector components from the sound field.

An acoustic beamformer is a device or system that is used to selectively amplify or attenuate sound waves coming from different directions in space. It is typically used in situations where there are multiple sound sources present and the goal is to isolate or enhance the sound from a particular direction or location.

The basic principle behind an acoustic beamformer is that it uses an array of sensors to capture sound waves from different directions. By processing the signals from these microphones in a specific way, the beamformer can create a “beam” of sound that is focused on a particular location or direction.

There are various types of acoustic beamformers, but they all generally work by using algorithms to adjust the phase and amplitude of the signals from the individual microphones in the array. By adjusting these parameters, the beamformer can create constructive interference for the desired sound source while cancelling out unwanted noise or interference from other directions.

Both APS (acoustic pressure sensor, i.e. microphones) and AVS devices can be employed in acoustic beamformers. A summary of AVS beamforming is presented is in Hawkes, M., and Nehorai, A. “Acoustic Vector-Sensor Beamforming and Capon Direction Estimation”, IEEE TRANSACTIONS ON SIGNAL PROCESSING, VOL. 46, NO. 9, September 1998. However, for airborne applications, very few AVS beamformers exist due high cost.

A wide variety of microphone arrangements for various APS arrays are presently available. Many designs have arrangements of microphones that help to attenuate the sidelobes of the array, which are responsible for ghost images. In general it can be stated that the array aperture, or the spatial breadth of the array, is inversely proportional to the lowest measurable frequency. Typical low frequency limits are about 250 Hz for a microphone array having breadth of 35 cm, or about 100 Hz if the size of the array size increases to a meter. The number of microphones in these arrays varies from a few to over 1000, depending on the shape of the beam pattern and degree of sidelobe rejection. The measurement aperture of all microphone-based APS array systems is much larger than the <1 cm (for one), or 12 cm (for two) for the accelerometer-based AVS composed of a MEMS microphone and triaxial MEMS accelerometer.

In addition to reduced aperture, there are other advantages of AVS compared to APS when used for beamforming. For APS systems, at least four sensors are required to focus the array in 3D, while a single AVS sensor represents four measurements at essentially the same point in space. Secondly, in an APS array, phase delay information is used to determine direction via beamforming, and depends on array geometry and frequency. An AVS has inherent directionality based on 3D sensing, which is frequency independent. Direct measurement of the direction-of-arrival (DOA) information is present in the velocity field structure, and resulting azimuth and elevation measurements are independent. Lastly, the enhanced phase diversity across coincident triaxial sensors improves measurement robustness to noise in AVS-based systems, which is possible for APS designs only by adding more sensors.

A single accelerometer-based AVS sensor can serve as a beamformer, with all four channels (accelerometer X, Y, Z, and microphone pressure referenced to the same position in space (within a few millimeters). A standard frequency-domain delay-and-sum beamformer can be created by computing the covariance matrix for each FFT bin, for each of four channels (one pressure and three acceleration) after integration of acceleration to velocity u:

$${R}_{v} = [ {y}_{v} {y}_{v}^{H} ] = [ \begin{matrix}{pp}^{*} & {pu}_{x}^{*} & {pu}_{y}^{*} & {pu}_{z}^{*} \\ {u}_{x} {p}^{*} & {u}_{x} {u}_{x}^{*} & {u}_{x} {u}_{y}^{*} & {u}_{x} {u}_{z}^{*} \\ {u}_{y} {p}^{*} & {u}_{y} {u}_{x}^{*} & {u}_{y} {u}_{y}^{*} & {u}_{y} {u}_{z}^{*} \\ {u}_{z} {p}^{*} & {u}_{z} {u}_{x}^{*} & {u}_{z} {u}_{y}^{*} & {u}_{z} {u}_{z}^{*}\end{matrix} ] \qquad ( Eqn . 1 )$$

The asterisk indicates the complex conjugate. So that the components of the matrix have similar magnitude, prior to calculating the covariance matrix the pressure p is normalized by dividing it by the product of air density times the speed of sound (Dall'Osto 2010 doi: 10.1109/OCEANS.2010.5663783). Then the resulting output of the beamformer has units of squared velocity. These directional results can be presented as dB referenced to 2.5e-m²/s², which results in a dB range equivalent to Sound Pressure Level (SPL), with a 20 μPa reference. These normalizations are for convenience of presentation, and alternatively one could scale the values such that the covariance matrix represents acoustic intensity, or squared pressure.

One Rᵥ matrix is obtained for each computed frequency bin. In practice, an FFT is performed for each pressure and velocity channel, and Eqn. 1 is computed for all bins less than the useful bandwidth of the system. For an acoustic plane wave in the far-field, a steering vector is computed as a function of azimuth (θ), elevation (φ), and frequency (ω):

$$a ( θ , φ , ω ) = {e}^{j ω \frac{cos ( φ ) cos ( θ ) {r}_{x} + cos ( φ ) sin ( θ ) {r}_{y} + sin ( φ ) {r}_{z}}{c}} \qquad ( Eqn . 2 )$$

The position of the AVS is described by the coordinate (rₓ, r_{y}, r_{z}), relative to a reference position. For just a single AVS, this is often taken as (0,0,0), so that Eqn. 2 reduces to a value of 1. The steering vector varies as the focus direction of the beamformer is changed. In some applications, such as autonomous monitoring of railway or traffic noise, a set of steering vectors is defined at the time of system installation for a specific grid of azimuth and elevation, and never changes thereafter. But for other applications, such as tracking a moving aircraft, the steering vectors must change in real-time.

Since for an AVS, the individual sensor elements observe the signal from different perspectives, the steering vector is weighted as per:

wₚ=1

wₓ=cos(φ)cos(θ)

w_{y}=cos(φ)sin(θ)

w_{z}=sin(φ)

a(θ,φ,ω)=[wₚ,wₓ,w_{y},w_{z}]^{T}*a(θ,φ,ω), (Eqn. 3)

so that the single sensor acoustic Delay-And-Sum (DAS) beamformer power P_{DAS} based on a triaxial MEMS accelerometer and MEMS microphone is:

P_{DAS}(θ,φ,ω)=a^{H}(θ,φ,ω)R(ω)a(θ, φ,ω) (Eqn. 4)

During operation, the beamformer finds regions in (θ, φ, ω) that maximize the power output P, facilitating airborne acoustic source location and tracking algorithms. Per each time step, a collection of accelerometer-based AVS (one or more) configured in such an array result in the estimation of one or more (θ, φ, ω) that are used as input to these tracking algorithms. Multiple (θ, φ, ω) are estimated if there are multiple sources in the environment, or one source emits power across a range of frequencies.

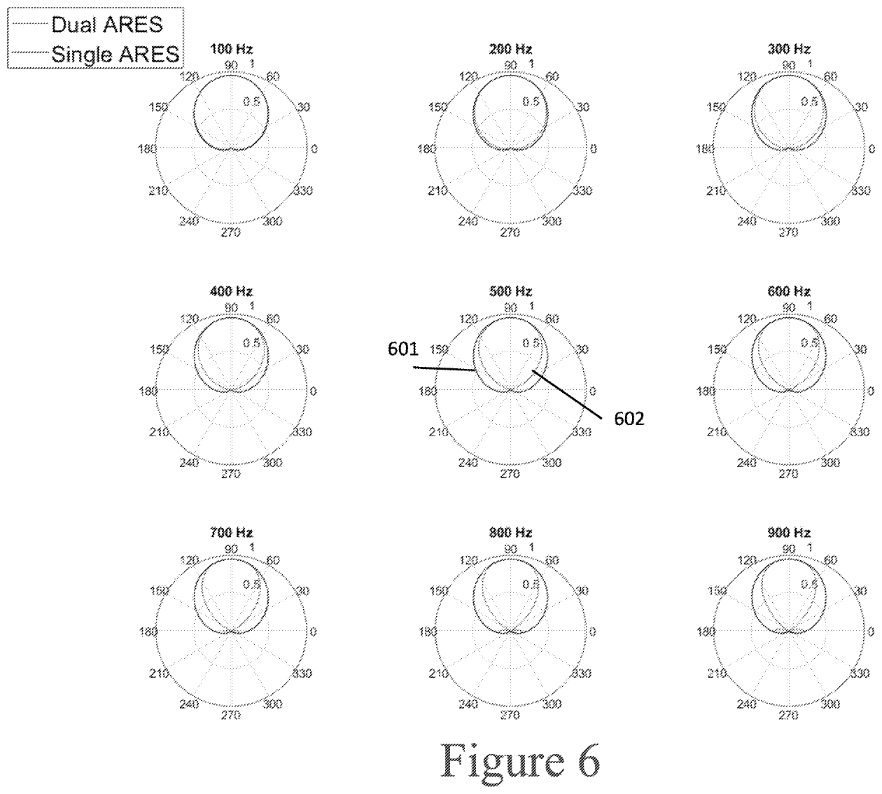

For the accelerometer-based single sensor acoustic beamformer, there can be virtually no sidelobes in the beam pattern, as shown by the black traces 601 in FIG. 6, when the array aperture is near zero. For the dual AVS beamformer (dashed traces 602), the beam pattern is narrower and thus more directional, and sidelobes start to appear at 500 Hz for an AVS separation distance set to ⅓ meter (half-wavelength at 500 Hz). This distance is more than may be desired for the 2 kHz bandwidth of the sensor. Normally, an accelerometer-based AVS beamformer composed of 2 sensors will have a separation of only 12 cm (half-wavelength at 1500 Hz).

The single sensor DAS beamforming equations 1-4 can be extended for multiple AVS configurations. The terms in the covariance matrix (Eqn. 1) become subscripted by which AVS the pressure and velocity measurements are derived from, e.g., p₁, uₓ₁, u_{y1}, u_{z1} for the first AVS, etc. The matrix then expands to 8×8 for a 2-AVS system, or 16×16 for a 4-AVS system. For an AVS-based beamformer in the far field, a plane wave assumption is made such that the azimuth and elevation angles remain the same for all AVS, and only the position offset of the sensors relative to a reference position (the rₓ, r_{y}, and r_{z} terms in Eqn. 2) is modified.

Using just two accelerometer-based AVS and the DAS algorithm implemented on a Raspberry Pi 4B embedded processor (RPi), angular separation of sources separated by less than 10 degrees is possible in real-time (either azimuth or elevation). The system runs at a 4.8 kHz sample rate, simultaneously sampling 8-channels from two 4-channel AVS. Front-end processing involves providing corrected pressure and scaled velocity outputs per channel to the RPi. The 2 kHz bandwidth of the system is presently limited by the accelerometer, though other MEMS accelerometer devices can be employed at higher bandwidths. Downstream of the FFT processing, the 8×8 covariance matrix is computed on every 20 ms time step, for each FFT bin from 50 Hz to 2000 Hz at 25 Hz intervals with 50% overlap.

To minimize processing time, the system can be focused in a predominate azimuth or elevation direction, as would be the case for the aforementioned traffic and rail monitoring applications. From that focus direction, bearing estimates are computed with typical resolutions of between 2 and 5 degrees in real-time. The beamformer output power in each frequency bin is used to determine one or more bearing estimates to acoustic sources (by the same or different processor), which must pass exceed predetermined noise and event duration thresholds. It is noted that for a suitable higher-performance backend processing system, no a priori focusing may be necessary.

Furthermore, the accelerometer-based AVS system can be run autonomously since noise sources not present in the targeted focus window are not recorded in the measured data. This can eliminate manual confirmation that measured sounds arise from the monitored location, rather than from other noises in the environment. For example, the beamformer focus of the system can be set to observe traffic across a roadway from a position above and to the side at a fixed azimuth, and distinguish noisy vehicles by traffic lane (mapped to elevation angle), train pass-bys from a sideline position, or aircraft noise emissions in a flightpath. As noted in U.S. patent application Ser. No. 17/332,390, multiple networked AVS “nodes” can collaborate in detection, characterization, and localization algorithms through triangulation means, or alternative joint positioning methods.

In light of these disclosures describing a capability to measure sound directivity with greatly reduced array aperture size, improved robustness to noise, with just two AVS providing selective bearing estimates to multiple noise sources, the system is configured to autonomously detect and record specific noise sources. Given the frequency domain aspect of the system, each source detection is distinguished in frequency, as well as bearing angle and beamformer power. This data can be considered an event signature and is logged to a cloud server, making possible supplemental and more computationally intensive analysis such as full-360 degree beamforming, as well as enhanced detection using machine learning techniques.

In summary, the disclosed airborne AVS composed of a lightweight triaxial accelerometer and microphone, both encased in foam and suspended in air has a very small array aperture, permits enhanced beamformer measurements with frequency independent spatial resolution, has much reduced spatial aliasing, and a near absence of ghost sources.

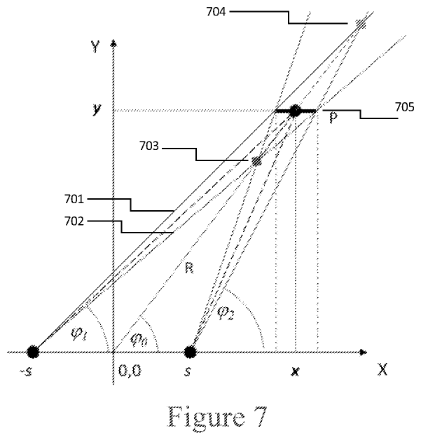

A geographically dispersed set of such sensors, observing the same noise sources and synchronized using a local or global time source such as GNSS, can triangulate the position of the source. While triangulation based on time-of-flight requires detection at 3 geographic locations, each AVS independently estimates both azimuth and elevation which enables triangulation of sounds with fewer than 3 sensors. A typical detection with two AVS is shown in FIG. 7 in two-dimensions (elevation angles not shown). The directional information from each AVS is accompanied by an error bound, such that the estimated azimuth angles φ₁ and φ₂ separated by known distance±s are known to a precision indicated by the solid and dashed lines 701 and 702 extending from the sensor in a direction corresponding to the detected sound source P. The expected position of P in x-y space is determined using a triangulation algorithm using data from two or more AVS nodes, which can be stated as within a certain range 703 to 704 and bearing 705 (as identified by the dark horizontal line). Because the beamformer can operate over multiple regions simultaneously, the system also provides a means for signal association to reduce ambiguity when there are multiple sources sounding simultaneously.

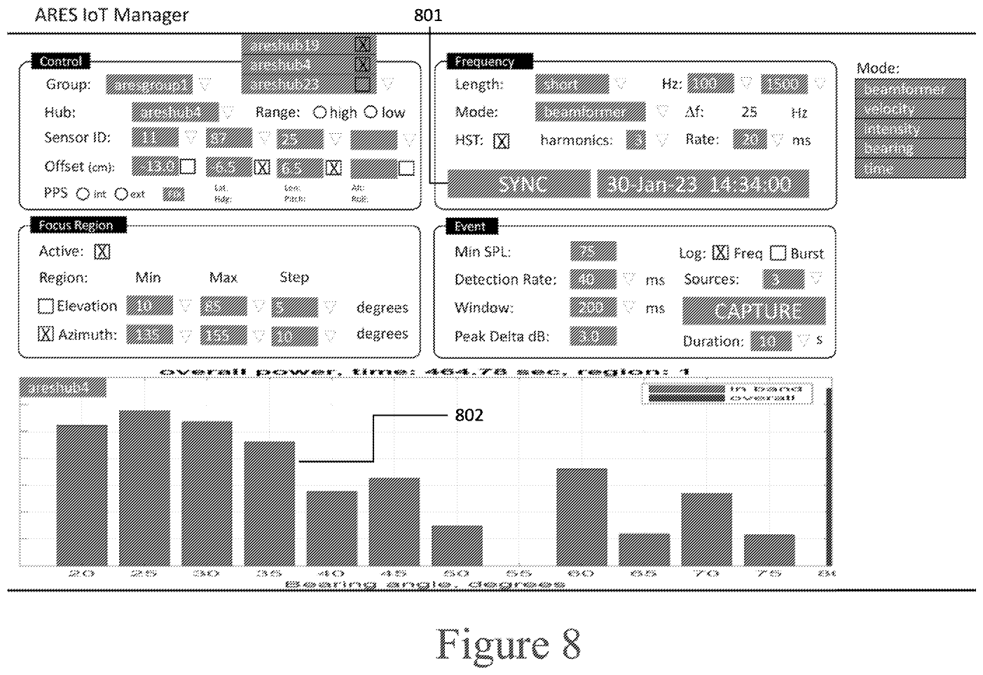

Orchestration of a multi-AVS system often occurs over a wide area network, so it is convenient to organize the sensors in a cloud-based test panel, called the ARES IoT Manager in FIG. 8. Multi-node synchronization is orchestrated by commanding all to start at a fixed UTC time, such that all sampling across the multi-node system is in sync 801, referenced to a global GNSS-derived time base.

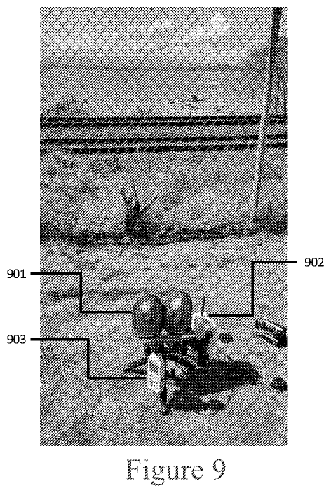

A photo of one practical use of the Accelerometer-base AVS disclosed herein is shown in FIG. 9. The two-AVS beamformer 901 is interfaced to a Raspberry Pi 902 which serves as the IoT hub to a cloud-based data service. The Raspberry Pi also has interfaces to a video camera so that visual information is fused to the acoustic beamformer result, and a standard integrating Sound Level Meter (SLM) 903 to provide a standards-based benchmark for the overall noise level. The Accelerometer-based AVS provides an estimate of the sound power per elevation and azimuth angle across the roadway, as depicted in the bar graph 802 at the bottom of FIG. 8. The AVS provides directional information to identify noise from specific directions. One practical example is to use the directional (e.g., traffic lane) information to levy a fine on specific vehicles that exceed a certain noise level, even if the overall noise measured at the SLM is the sum of sound emissions from several vehicles in different lanes.

The utility of the disclosed AVS applies to many such environmental noise monitoring situations. Another example is when the accelerometer-based AVS is positioned beside railroad tracks to observe noise from passing trains. Trains produce a wide variety of noise types, some of which are annoying to communities near the tracks. Providing directional and frequency information allows an AVS system to autonomously discriminate specific noises from the train compared to other sources, and from what part of the train, which car, and even what subassembly. Prior art sound level meter-based monitoring systems without directional data cannot automatically log environmental noise with attribution of the noise source (rolling noise, curve squeal, aerodynamic, etc.).

What is claimed is:

1. An airborne acoustic vector sensor for simultaneous measurement of triaxial particle acceleration in three dimensions, together with pressure, comprising:
a triaxial MEMS accelerometer;
a MEMS microphone sensitive to sound pressure having at least partial overlap in frequency with the accelerometer;
a lightweight solid body having a density less than a threshold multiple of that of air, in which both the accelerometer and microphone are mounted within; and
a suspension system which supports the solid body containing both the accelerometer and microphone within a framework.

2. A calibration method for an acoustic vector sensor composed of a MEMS triaxial accelerometer and a MEMS microphone mounted within and encased by a lightweight closed cell solid body having a density less than a threshold multiple of that of air, the method comprising:
emitting, by a sound source, calibration sound signals in a controlled environment;
detecting, by a reference microphone positioned outside the solid body in the same sound field as the acoustic vector sensor, the calibration sound signals emitted by the sound source; and
calibrating amplitude and phase calibration factors for the MEMS microphone using the calibration sound signals detected by the external reference microphone, to correct a response of the MEMS microphone,
wherein upon application of the calibration factors the response of the MEMS microphone as corrected is representative of a signal at the reference microphone;
such that a phase center of measurements by the MEMS microphone and the accelerometer is governed by physical separation of the MEMS microphone and the accelerometer within the closed cell solid body.

3. An airborne acoustic beamformer composed of one or more MEMS triaxial accelerometers and one or more MEMS microphones,
wherein each triaxial accelerometer and microphone are collocated within and encased by a lightweight closed cell solid body having a density less than a threshold multiple of that of air,
and the solid body within which each triaxial accelerometer and microphone are collocated is supported within a framework by a suspension system,
such that a phase center of measurements of each triaxial accelerometer and microphone is governed by physical separation thereof within the closed cell solid body.

4. The airborne acoustic beamformer of claim 3, wherein the MEMS triaxial accelerometers and the MEMS microphones comprises a single MEMS triaxial accelerometer and a single MEMS microphone encased within a single solid body,
such that a phase center of the airborne acoustic beamformer is governed by the separation between the single MEMS triaxial accelerometer and the single MEMS microphone.

5. The airborne acoustic beamformer of claim 3, wherein the MEMS triaxial accelerometers and the MEMS microphones are encased within a plurality of the solid bodies,
such that an array aperture of the airborne acoustic beamformer is governed by the separation between the solid bodies.

6. A real-time airborne acoustic beamformer apparatus composed of a sampling system to sample acceleration of one or more MEMS triaxial accelerometers and one or more MEMS microphones;
a processor to calculate the Fourier Transform of pressure and acoustic particle velocity from the sampled acceleration, and to apply a magnitude and phase correction vector to the pressure to correct for effects of encasing the microphones in foam;
the same or another processor to compute beamformer power in selected elevation and azimuth segments, and
provide representative bearing estimates to a set of one or more acoustic sources.
